(19) United States
(12) Patent Application Publication
(10) Pub. No.: US 2002/0125470 A1
(43) Pub. Date: Sep. 12, 2002

(54) Multiwall nanotube and process for oxidizing only the outer wall of a multiwall nanotube

(76) Inventors: Wolfgang Hoenlein, Unterhaching (DE); Eugen Unger, Augsburg (DE)

Correspondence Address: Craig Gregersen, Briggs and Morgan, P.A., W2200 First National Bank Building, St. Paul, MN, 55101, US

(21) Appl. No.: 09/919,115

(22) Filed: Aug. 1, 2001

(30) Foreign Application Priority Data
Aug. 4, 2000 (DE) 10038124.3

(51) Int. Cl. H01L 47/00

(52) U.S. Cl. 257/1

(57) ABSTRACT

The invention relates to a multiwall nanotube having an outer wall and at least one inner wall, in which only the outer wall is oxidized and the inner wall or walls is/are not oxidized.

The invention provides a multiwall nanotube in which only the outer wall is oxidized and a process for oxidizing only the outer wall of a multiwall nanotube.

Multiwall nanotubes are known from [1].

Furthermore, carbon nanotubes and processes for producing them are known from [19 . A typical multiwall nanotube has a diameter of some 10s of nanometers, and the length of a nanotube can be a number of microns. The ends of a nanotube are typically each capped, i.e. covered, by half a fullerene molecule.

A nanotube can have one or more walls. In the case of multiwall nanotubes, at least one inner nanotube is surrounded coaxially by an outer nanotube [1].

Depending on the chirality, nanotubes have either the properties of a metal or the properties of a semiconductor. Furthermore, this conductivity can be controlled by application of an electric field (known as the field effect) [2] and/or by doping the carbon nanotubes with boron nitride, as described in [3]. In the latter case, a nanotube doped with boron atoms and nitrogen atoms is also referred to as a boron nitride nanotube.

Owing to the suitability of the nanotubes as metallic conductors and as semiconductors, it would, for the purposes of nanocircuit technology, be desirable to apply such single-wall and multiwall nanotubes to solid substrates.

This has hitherto been achieved by making a substrate hydrophobic, for example by treatment with trialkyl-substituted silazane compounds, and subsequently fixing the nanotubes thereon by means of van der Waal forces [4]. However, it is possible for the nanotubes to move by slipping on the substrate when applied in this way. This slipping has a considerable adverse effect on both the desired predetermined structure and the long-term stability of such circuits constructed using nanotubes.

Furthermore, [5] describes the chemical functionalization of nanotubes for the purpose of immobilizing them on substrates, and [6] describes the immobilization of nanotubes on substrates and the use in this way of multiwall nanotubes.

The immobilization of microspheres of an organic or inorganic nature on substrates is described in [7].

Owing to the growing interest in nanocircuit technology, there is a need for nanotubes having electronic properties which make them suitable for use in nanocircuit technology.

It is thus an object of the invention to provide such nanotubes.

This object is achieved by a multiwall nanotube having an outer wall and at least one inner wall, in which only the outer wall is oxidized and the inner wall or walls is/are not oxidized.

Such a selective oxidation of only the outer wall of a multiwall nanotube brings two particular advantages with it.

Firstly, a multiwall nanotube in which only the outer wall is oxidized can bind covalently and thus in a slip-resistant manner to a substrate.

Secondly, the substantial oxidation of only the outer wall of the multiwall nanotube leads to an electrically insulating effect, so that the outer wall of the multiwall nanotube loses its ability to conduct electric current.

However, one or more of the inner nanotubes of the multiwall nanotube then takes over conduction of the electric current because this inner nanotube or nanotubes of the multiwall nanotube is protected from chemical oxidation by the outer wall of the multiwall nanotube.

Such a retention of the conductivity of the inner nanotube(s) with loss of the conductivity of the outer wall of the multiwall nanotube is particularly advantageous for the construction of nanocircuits, since such external electrical insulation makes possible the crosswise construction of such nanocircuits without an electric short circuit occurring between the crossing nanotubes.

It may be pointed out in this context that when the outer wall of a multiwall nanotube is chemically changed in a targeted manner, the conduction of electricity through the multiwall nanotube is automatically taken over by the next inner nanotube. Thus, in a manner analogous to a rubber-sheathed electric wire, a nanostructure which is especially suitable for conduction of electricity in nanocircuits is created.

In one embodiment of the invention, the multiwall nanotube can be, for example, a multiwall carbon nanotube or a multiwall nanotube doped with boron nitride.

The invention also provides a process for oxidizing only the outer wall of a multiwall nanotube. In this process, a multiwall nanotube is firstly made available. The multiwall nanotube is then subjected to oxidation. Finally, the multiwall nanotube which has been treated in this way is isolated.

In one embodiment of the process, the multiwall nanotube used is a multiwall carbon nanotube or a multiwall nanotube doped with boron nitride.

In a further embodiment of the process, the outer wall of the multiwall nanotube is oxidized by reaction with a strong acid.

In a further embodiment of the process, nitric acid, sulfuric acid, chromic acid, Caro's acid, perchloric acid, iodic acid or organic peracids are used as strong acid.

In a further embodiment of the process, sulfuric acid is used as a mixture with hydrogen peroxide.

In a further embodiment of the process, the outer wall of the multiwall nanotube is oxidized at room temperature or at a temperature up to the boiling point of the respective reaction mixture.

A substrate has bound onto its surface a multiwall nanotube in which only the outer wall is oxidized.

An electronic component comprises a substrate and multiwall nanotubes in which only the outer wall is oxidized are bound to the substrate.

In a process for binding a multiwall nanotube to a substrate, chemically reactive groups are generated on the outer wall of the multiwall nanotube in a first step and the multiwall nanotube which has been chemically modified in this way is, in a second step, brought into contact with the substrate so that covalent chemical bonds are formed between the substrate and the chemically reactive groups which have been generated on the outer wall of the multiwall nanotube.

The carbon framework of the outer wall of the multiwall nanotube is functionalized by generation of reactive groups. These chemically reactive groups generated on the outer wall of the multiwall nanotube subsequently react with groups present on the substrate which are able to react with the chemically reactive groups on the outer wall of the nanotube so that a covalent bond is formed between the two.

As substrate, it is possible to use materials which bear such chemically reactive groups. For example, substrates based on silicon, for example glass (SiO₂), bear hydroxyl groups. As an alternative, a substrate made of material which does not bear such chemically reactive groups can be coated with a further material bearing such chemically reactive groups. In the case of the substrate, nucleophiles are particularly preferred as chemically reactive groups.

A particularly useful method of functionalizing the outer wall of the multiwall nanotube is, for example, oxidation of a large number of the carbon atoms present in this wall to generate chemically reactive groups.

Furthermore, the multiwall nanotube which has been chemically modified in this way can be separated off by filtration alone or by precipitation and filtration prior to bringing it into contact with the substrate.

In a further embodiment of the invention, the multiwall nanotube which has been chemically modified in this way is, after it has been separated off but before it is brought into contact with the substrate, dispersed in a suitable medium.

In a further embodiment of the invention, the chemically reactive groups on the outer wall of the multiwall nanotube are generated by means of oxidation of the outer wall by reaction with a strong oxidizing acid.

Strong oxidizing acids which can be used are nitric acid, sulfuric acid, chromic acid, Caro's acid, perchloric acid, iodic acid or organic peracids.

Furthermore, it is possible to use sulfuric acid as a mixture with hydrogen peroxide.

The generation of chemically reactive groups on the outer wall of the multiwall nanotube can be carried out at room temperature or up to a temperature corresponding to the boiling point.

Furthermore, one embodiment of the invention provides for the substrate to bear chemically reactive groups which are able to form a covalent bond with the chemically reactive groups generated on the outer wall of the multiwall nanotube.

The chemically reactive groups on the substrate may be nucleophiles, for example hydroxyl groups.

The groups generated on the outer wall of the multiwall nanotube may be carboxyl functions. Before the nanotube is brought into contact with the substrate, the carboxyl groups can be treated with a reagent for promoting covalent bonding, with it being possible to use SOCl₂, COCl₂, PCl₃, CCl₄ and Ph₃P, PhCOCl, ClCOCOCl or Cl₂CHOMe as halogenating reagent in the case of acid chloride formation and carbodiimides or mineral acids as coupling reagent in the case of direct reaction of acid groups and hydroxyl groups.

When thionyl chloride is used as halogenating reagent for activating the carboxyl groups generated on the outer wall of the multiwall nanotube, a further embodiment of the invention provides for a base to be additionally used in order to neutralize the hydrochloric acid formed in the reaction between the acid chloride on the outer wall of the multiwall nanotube and the hydroxyl groups on the substrate.

In a further embodiment of the invention, the base used for neutralization is preferably a nonnucleophilic base, advantageously an alkyl-substituted amine such as triethylamine or diisopropylamine, or imidazole, pyridine or a mixture of potassium tert-butoxide and tert-butanol.

Additional features of the invention will now be explained with the aid of the embodiments described below with reference to the drawing.

Illustrative embodiments of the invention are shown in the figures and are explained in more detail below.

In the figures:

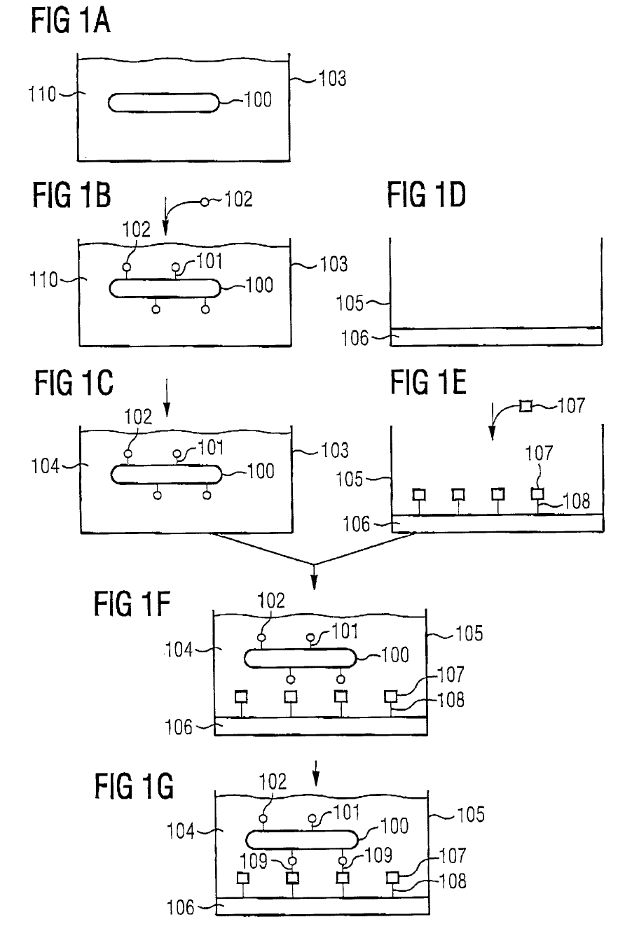

FIG. 1 schematically shows the functionalization of the multiwall nanotube and its application to the substrate in accordance with one embodiment of the invention and

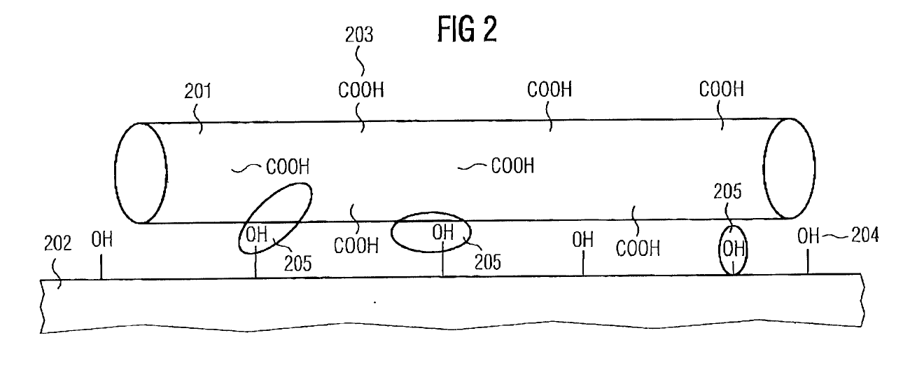

FIG. 2 shows a schematically enlarged depiction of a multiwall nanotube functionalized by means of carboxyl groups with covalent bonding to the substrate.

FIG. 1a shows a multiwall nanotube 100 in a container 103 containing a medium 110 before generation of chemically reactive groups on the outer wall of the multiwall nanotube 100.

FIG. 1b shows the nanotube 100 bearing chemically reactive groups 102 which have been generated on the outer wall of the multiwall nanotube 100 by means of a covalent bond 101.

Such functionalization of the outer wall of the multiwall nanotube 100 is, in this example, carried out by reaction with a strongly oxidizing acid.

For this purpose, preference is given, for example, to the use of concentrated nitric acid (up to 100 percent by weight), chromic acid, Caro's acid, sulfuric acid or mixtures of sulfuric acid and hydrogen peroxide, perchloric acid, iodic acid or organic peracids.

The reaction can be carried out at room temperature or at a temperature up to the boiling point of the respective acid-containing medium. The treatment with a strong oxidizing acid in an aqueous environment converts carbon atoms on the outer wall of the multiwall nanotube into the corresponding carboxylic acid groups.

After the generation of chemically reactive groups 102 on the surface of the outer wall of the multiwall nanotube 100, the nanotubes 100 which have been chemically modified in this way can, if desired, be separated off from the acid-containing medium 110 by filtration alone or by successive precipitation and filtration.

The functionalized nanotubes 100 which have been separated off can then, if desired, be washed and then dispersed in a second medium 104 or, without being washed first, dispersed in a second medium 104 directly after they have been separated off, as shown in FIG. 1c.

The result of dispersing the nanotubes 100 which have been chemically modified in this way is shown in FIG. 1c.

In a further embodiment of the invention, the multiwall nanotube 100 dispersed in the medium 104 in FIG. 1c can be reacted with a further reagent to further functionalize the chemically reactive groups 102 generated on the outer wall of the multiwall nanotube 100 in order to activate them in respect of reaction with a nucleophile. In this way, the later formation of a covalent bond with the preferably nucleophilic groups on the substrate is aided.

When the groups 102 generated on the outer wall of the multiwall nanotube 100 are carboxyl groups, such activation can be carried out by addition of a known halogenating agent such as SOCl₂, or in the case of direct reaction of the carboxyl groups with hydroxyl groups of the substrate, a known coupling reagent such as carbonyldiimidazole, dicyclohexylcarbodiimide or mineral acids. As an alternative to SOCl₂ for conversion into the corresponding acid chloride, it is also possible to use COCl₂, PCl₃, PCl₅, (CCl₄ and Ph₃P), PhCOCl, ClCOCOCl or Cl₂CHOMe.

FIG. 1d shows the case in which a substrate 106 in a substrate housing 105 does not comprise a material bearing chemically reactive groups.

In this case, the chemically reactive groups 107 are firstly applied to the substrate by means of known methods, for example by coating with a material bearing chemically reactive groups.

FIG. 1e shows the substrate 106 in the substrate housing 105, where the substrate material either already bears chemically reactive groups 107 or where such chemically reactive groups 107 have been applied to the surface of the substrate 106 via the covalent bond 108.

In each case, the surface of the substrate 106 is preferably hydrophilic, so that good adhesion of the multiwall nanotube 100 which has likewise been made hydrophilic by functionalization is ensured.

FIG. 1f shows the contacting of the medium 104 in which the functionalized multiwall nanotubes 100 are present with the substrate 106. If thionyl chloride or another halogenating reagent has been used in the step depicted in FIG. 1c for activating the carboxyl groups generated on the outer wall of the multiwall nanotube 100, an additional base can be added in the step depicted in FIG. 1f.

Such a base serves to neutralize the hydrochloric acid which is formed in the reaction between the acid chloride functions on the outer wall of the multiwall nanotube and the hydroxyl groups on the substrate.

Thus, during the formation of the covalent bond 109 between the nanotube 100 and the substrate 106, in which acid is formed, the addition of a base prevents the counterreaction, namely the acid hydrolysis of the ester group formed between the nanotube 100 and the substrate 106, from taking place.

For this purpose, preference is given to using non-nucleophilic bases, for example alkyl-substituted amines such as triethylamine or diisopropylamine, or alternatively imidazole, pyridine or a mixture of potassium tert-butoxide and tert-butanol.

FIG. 1g shows the covalent bond 109 between the functionalized multiwall nanotube 100 and the substrate 106.

The multiwall nanotube 100 which has been bound to the substrate 106 in this way therefore does not slip on the surface of the substrate 106. This slip resistance makes possible a stability not achieved hitherto in the construction of nanocircuits.

FIG. 2 shows a schematically enlarged depiction of a nanotube 201 functionalized with carboxyl groups 203 on being brought into contact with hydroxyl groups 204 on the surface of the substrate 202.

In this embodiment, the carboxyl groups 203 of the outer wall of the multiwall nanotube 201 have not been modified by means of a halogenating reagent.

The regions in which the formation of an ester bond between the multiwall nanotube and the substrate takes place are highlighted by means of ellipses 205.

In this document, the following publications are cited:

[1] P. M. Ajayan, Nanotubes from Carbon, Chem. Rev. 99, pp. 1787-1799, 1999

[2] W. Han et al., Synthesis of Boron Nitride Nanotubes From Carbon Nanotubes by a substitution Reaction, Applied Physics Letters, Volume 73, Number 21, pp. 3085-3087, November 1998

[3] R. Martel et al., Single- and Multi-Wall Carbon Nanotube Field-Effect Transistors, Applied Physics Letters, Volume 73, Number 17, pp. 2447-2449, October 1998

[4] G. S. Duesberg, W. J. Blau et al., Chemical Physics Letters 310 (1999) 8-14

[5] WO 97/32571

[6] WO 01/03208

[7] DE 69221826 T2

1. A multiwall nanotube having an outer wall and at least one inner wall, wherein
only the outer wall is oxidized, and
the inner wall or walls is/are not oxidized.

2. A multiwall nanotube as claimed in claim 1 which is a multiwall carbon nanotube or a multiwall nanotube doped with boron nitride.

3. A process for oxidizing only the outer wall of a multiwall nanotube, which comprises
providing a multiwall nanotube,
subjecting the multiwall nanotube to oxidation, and
isolating the multiwall nanotube which has been treated in this way.

4. The process as claimed in claim 3, wherein the multiwall nanotube used is a multiwall carbon nanotube or a nanotube doped with boron nitride.

5. The process as claimed in claim 3 or 4, wherein the oxidation is carried out by reaction with a strong acid.

6. The process as claimed in claim 5, wherein the strong acid used is nitric acid, sulfuric acid, chromic acid, Caro's acid, perchloric acid, iodic acid or an organic peracid.

7. The process as claimed in claim 6, wherein sulfuric acid is used as a mixture with hydrogen peroxide.

8. The process as claimed in any of claims 3 to 7, wherein the oxidation of the outer wall of the multiwall nanotube is carried out at room temperature or at a temperature up to the boiling point of the respective reaction mixture.

9. A substrate on which a multiwall nanotube as claimed in claim 1 or 2 is bound.

10. An electronic component comprising a substrate as claimed in claim 9.
